(19) United States
(12) Patent Application Publication
(10) Pub. No.: US 2013/0229813 A1
(43) Pub. Date: Sep. 5, 2013

(54) LUMINAIRE

(71) Applicants: Ryotaro MATSUDA, Kanagawa-ken (JP); Hiroshi Takenaga, Kanagawa-ken (JP); Yoshihiro Aonami, Kanagawa-ken (JP); Takumi Suwa, Kanagawa-ken (JP); Makoto Sakai, Kanagawa-ken (JP); Takuro Hiramatsu, Kanagawa-ken (JP)

(72) Inventors: Ryotaro MATSUDA, Kanagawa-ken (JP); Hiroshi Takenaga, Kanagawa-ken (JP); Yoshihiro Aonami, Kanagawa-ken (JP); Takumi Suwa, Kanagawa-ken (JP); Makoto Sakai, Kanagawa-ken (JP); Takuro Hiramatsu, Kanagawa-ken (JP)

(73) Assignee: Toshiba Lighting & Technology Corporation, Kanagawa-ken (JP)

(21) Appl. No.: 13/530,450

(22) Filed: Jun. 22, 2012

(30) Foreign Application Priority Data
Mar. 1, 2012 (JP) 2012-045541

(51) Int. Cl. F21V 29/00; H05K 13/00

(52) U.S. Cl. 362/382; 29/592.1

(57) ABSTRACT

According to one embodiment, a luminaire includes a main body part, a holding part at least a part of which is provided inside the main body part, a light source part that is provided on one end side of the main body part and includes a light-emitting element, a control part that is provided inside the holding part and controls the light-emitting element, an area control part that is provided between the control part and the holding part and includes a concave part, and a first heat transfer part that is provided inside the concave part and between the control part and the holding part.

### CROSS-REFERENCE TO RELATED APPLICATIONS

This application is based upon and claims the benefit of priority from the prior Japanese Patent Application No. 2012-045541, filed on Mar. 1, 2012; the entire contents of which are incorporated herein by reference.

### FIELD

Embodiments described herein relate generally to a luminaire.

### BACKGROUND

Recently, a luminaire using a light-emitting diode (LED) as a light source is put into practical use.

Since the luminaire using the light-emitting diode has long life and low power consumption, the luminaire is expected to replace an existing filament bulb (incandescent lamp) or the like.

In the luminaire as stated above, heat generated in a control part provided with a lighting circuit to supply power to the light-emitting diode is released to the outside through a main body part. For that purpose, a technique is proposed in which a filling material is filled in a space between the control part and the main body part, and a heat radiation property is improved.

However, if the filling material is simply filled, there is a fear that the weight of the luminaire becomes too heavy.

### DESCRIPTION OF THE DRAWINGS

FIG. 1 is a schematic sectional view for illustrating a luminaire 1 of an embodiment.

FIG. 2 is a schematic view for illustrating an area control part 9.

FIG. 3 is a schematic perspective view for illustrating a heat transfer part 14.

FIG. 4 is a schematic graph for illustrating effects of a heat transfer part 8 and the heat transfer part 14.

### DETAILED DESCRIPTION

According to a first aspect, a luminaire includes a main body part, a holding part at least a part of which is provided inside the main body part, a light source part that is provided on one end side of the main body part and includes a light-emitting element, a control part that is provided inside the holding part and controls the light-emitting element, an area control part that is provided between the control part and the holding part and includes a concave part, and a first heat transfer part that is provided inside the concave part and between the control part and the holding part.

Since this luminaire includes the first heat transfer part, heat generated in the control part can be released by heat conduction. Besides, since the area control part is provided, the first heat transfer part is easily formed in a desired area of the control part. Thus, the increase of weight of the first heat transfer part can be suppressed. As a result, improvement of heat radiation property and suppression of weight increase of the luminaire can be realized.

According to a second aspect, a luminaire includes a main body part, a holding part at least a part of which is provided inside the main body part, a light source part that is provided on one end side of the main body part and includes a light-emitting element, a control part that is provided inside the holding part and controls the light-emitting element, and a second heat transfer part that includes a heat receiving part at least a part of which contacts the holding part, and a heat conducting part provided between the heat receiving part and the main body part. The heat receiving part is provided to face a high temperature area of the control part.

Since this luminaire includes the second heat transfer part, heat generated in the control part can be released by heat conduction. Besides, since the heat receiving part is provided to face the high temperature area of the control part, the increase of weight of the second heat transfer part can be suppressed. As a result, improvement of heat radiation property and suppression of weight increase of the luminaire can be realized.

According to a third aspect, the luminaire according to the first aspect further includes a second heat transfer part that includes a heat receiving part at least a part of which contacts the holding part, and a heat conducting part provided between the heat receiving part and the main body part. The heat receiving part is provided to face the first heat transfer part through the holding part.

Since this luminaire further includes the second heat transfer part, the heat generated in the control part can be more efficiently released. Besides, since the heat receiving part is provided to face the first heat transfer part through the holding part, the increase of weight of the second heat transfer part can be suppressed.

According to a fourth aspect, in the luminaire according to the first or the third aspect, the area control part covers a first area of the control part, the first heat transfer part covers a second area of the control part, and the second area has a higher temperature than the first area when the light-emitting element is controlled.

Since this luminaire includes the first heat transfer part provided for the second area the temperature of which becomes high, the heat generated in the control part can be further efficiently released.

According to a fifth aspect, in the luminaire according to the fourth aspect, the second area is provided on a light source part side of the control part.

Since the temperature of the control part on the light source part side is liable to become high, when the light source part side of the control part is made the second area, the heat generated in the control part can be further efficiently released.

According to a sixth aspect, in the luminaire according to the second aspect, a contact portion of the heat receiving part that contacts the holding part has a plane shape, and at least a part contacts an outer wall of the holding part.

According to this luminaire, the heat generated in the high temperature area of the control part can be efficiently released.

According to a seventh aspect, in the luminaire according to the second aspect, the heat conducting part has a plate shape.

According to this luminaire, reduction of weight of the heat conducting part, and suppression of weight increase of the luminaire can be realized.

According to an eighth aspect, in the luminaire according to the second aspect, the high temperature area of the control part is provided on a light source part side of the control part.

Since the temperature of the control part on the light source side is liable to become high, when the light source part side of the control part is made the high temperature area of the control part, the heat generated in the control part can be further efficiently released.

According to a ninth aspect, in the luminaire according to the second aspect, the heat receiving part and the heat conducting part are formed integrally with the main body part.

According to this luminaire, the heat conduction in the second heat transfer part can be efficiently performed.

According to a tenth aspect, in the luminaire according to the second aspect, the second heat transfer part is made of a metal.

According to this luminaire, the heat conduction in the second heat transfer part can be efficiently performed.

According to an eleventh aspect, in the luminaire according to the first aspect, a density of the area control part is lower than a density of the first heat transfer part.

According to this luminaire, the suppression of weight increase of the luminaire can be realized.

According to a twelfth aspect, in the luminaire according to the first aspect, the area control part includes a hollow structure.

According to this luminaire, the suppression of weight increase of the luminaire can be realized.

According to a thirteenth aspect, in the luminaire according to the first aspect, the first heat transfer part has an insulating property.

According to this luminaire, the insulating property relative to the control part can be ensured.

According to a fourteenth aspect, in the luminaire according to the first aspect, the area control part has an insulating property.

According to this luminaire, the insulating property relative to the control part can be ensured.

According to a fifteenth aspect, in the luminaire according to the first aspect, the holding part has a tubular shape, one end protrudes from the main body part, and a sealing part is provided inside the end of the holding part on the side protruding from the main body part.

According to this luminaire, intrusion of water or the like into the inside of the luminaire from the end of the holding part on the side protruding from the main body can be prevented.

Hereinafter, embodiments will be described with reference to the drawings. Incidentally, in the respective drawings, the same component is denoted by the same reference numeral and a detailed description thereof is suitably omitted.

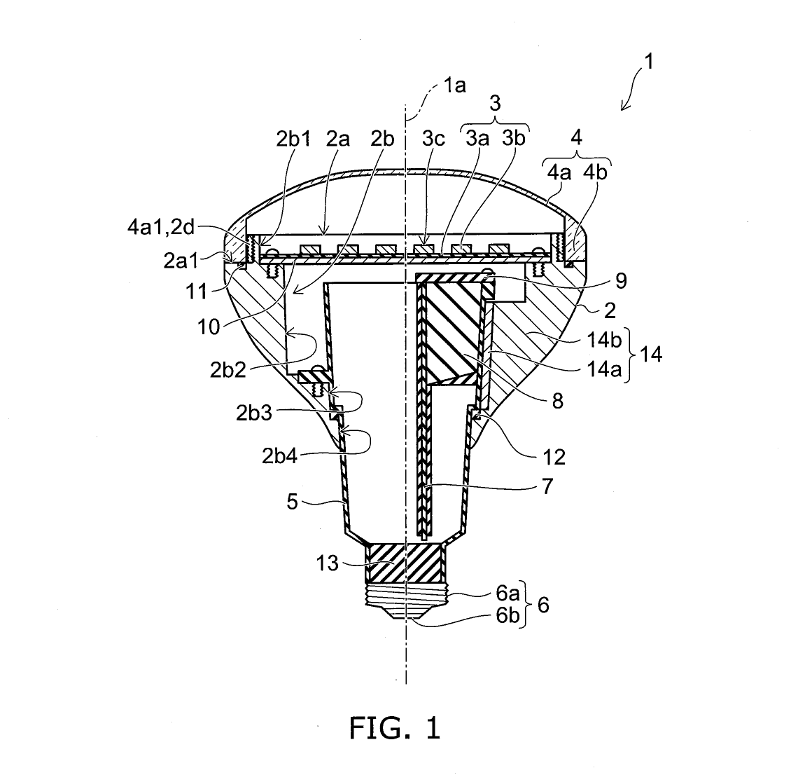

FIG. 1 is a schematic sectional view for exemplifying a luminaire 1 of an embodiment.

As shown in FIG. 1, the luminaire 1 includes a main body part 2, a light source part 3, a cover part 4, a holding part 5, a cap part 6, a control part 7, a heat transfer part 8 (corresponding to an example of a first heat transfer part), and an area control part 9.

The main body part 2 can be made to have such a shape that the cross section in a direction perpendicular to an axial direction gradually increases from the cap part 6 side to the cover part 4 side. However, no limitation is made to this, and the main body part can be suitably changed according to, for example, the size of the light source part 3 and the cap part 6. In this case, if the outer shape and the size of the main body part 2 are the same as the outer shape and the size of an existing filament bulb, the existing filament bulb can be easily replaced.

The main body part 2 can be made of, for example, a material having a high thermal conductivity. The main body part 2 can be made of a metal such as, for example, magnesium (Mg), aluminum (Al), copper (Cu) or alloy of these. However, no limitation is made to these, and the main body part can also be made of, for example, an inorganic material, such as aluminum nitride (AlN) or alumina (Al₂O₃), or an organic material such as high thermal conductive resin.

Besides, plural not-shown thermal radiation fins are provided on the outer wall of the main body part 2, and the heat radiation property can be improved.

A concave part 2b1 is provided on one end face 2a of the main body part 2, and a concave part 2b2 is provided on a bottom of the concave part 2b1. Besides, a concave part 2b3 is provided on a bottom of the concave part 2b2, and a hole 2b4 is provided in a bottom of the concave part 2b3. That is, a stepped hole 2b passing through the center of the main body part 2 in the axial direction is provided.

The light source part 3 is provided on the bottom of the concave part 2b1 through an attachment plate 10. That is, the light source part 3 including a light-emitting element 3b is provided on one end side of the main body part 2. The attachment plate 10 has a flat plate shape, prevents the light source part 3 from bending, and conducts heat generated in the light source part 3 to the main body part 2. The attachment plate 10 can be made of, for example, a metal such as aluminum. However, the material of the attachment plate 10 is not limited to this, and a material having a certain degree of rigidity and having a high thermal conductivity can be used.

The light source part 3 includes, for example, a board 3a and the light-emitting element 3b provided on the board 3a.

The board 3a can be made such that a wiring pattern is formed on the surface of a base member using a resin. Besides, the board 3a can also be made such that a wiring pattern is formed on the surface of a base member using a material having a high thermal conductivity. As the material having the high thermal conductivity, for example, an inorganic material such as aluminum nitride, and an organic material such as high thermal conductive resin can be exemplified.

The light-emitting element 3b can be made, for example, a so-called self light-emitting element such as a light-emitting diode, an organic light-emitting diode or a laser diode.

An irradiation surface 3c of the light-emitting element 3b is provided to be perpendicular to a center axis la of the luminaire 1, and radiates light mainly in the axial direction of the luminaire 1. The number of light-emitting elements 3b is not limited, and one or more light-emitting elements 3b are provided according to the use of the luminaire 1, the size of the light-emitting element 3b or the like. When the plural light-emitting elements 3b are provided, the light-emitting elements may be arranged in a regular form such as a matrix shape, a staggered shape or a radial shape, or may be arranged in an arbitrary form.

When the light-emitting element 3b is a light-emitting diode, a not-shown wavelength conversion part including a phosphor may be provided on the irradiation surface 3c side.

In this case, the phosphor absorbs a part of light emitted from the light-emitting element 3b and generates fluorescence having a specified wavelength. For example, the phosphor absorbs a part of blue light emitted from the light-emitting element 3b and generates yellow fluorescence. In this case, the blue light not absorbed by the phosphor and the yellow light emitted from the phosphor are mixed and become a white light.

However, the color of the light emitted from the light-emitting element 3b including the not-shown wavelength conversion part can be suitably changed according to the use of the luminaire 1 or the like. For example, a light with a color temperature of 2800K or higher and 3000K or lower (bulb color) can be emitted from the light-emitting element 3b including the not-shown wavelength conversion part.

The cover part 4 is provided on the irradiation side of the light source part 3, and includes a transmission part 4a and a fastening part 4b. The transmission part 4a includes a curved surface protruding toward the irradiation direction of the luminaire 1. The transmission part 4a allows the light emitted from the light source part 3 to pass through. Thus, the transmission part 4a is made of a material having translucency.

In this case, when consideration is given to a case where the luminaire 1 is installed outdoors, the transmission part 4a is preferably made of a material having transparency and weather resistance. As the material having transparency and weather resistance, for example, acryl resin can be exemplified.

Besides, the transmission part 4a may include an optical component for condensing or scattering light. For example, the transmission part 4a may include a lens, a prism, asperities or the like.

The fastening part 4b has an annular shape, and is provided to protrude from the peripheral part of the transmission part 4a. A female screw part 4a1 is provided inside the annular transmission part 4a, and a male screw part 2d adapted to the female screw part 4a1 is provided on the main body part 2.

Thus, the attachment and detachment of the cover part 4 can be facilitated.

Besides, the fastening part 4b is provided integrally with the transmission part 4a. For example, the fastening part 4b may be bonded to the transmission part 4a, or the transmission part 4a and the fastening part 4b may be integrally molded. Besides, a groove is provided in an end face 2a1 of the main body part 2, and a seal member 11 is provided inside the groove. When the cover part 4 is attached to the main body part 2, the end face of the fastening part 4b contacts the seal member 11, and a gap between the cover part 4 and the main body part 2 is hermetically sealed. Thus, when the luminaire 1 is installed outdoors, intrusion of water or the like into the inside of the luminaire 1 from the gap between the cover part 4 and the main body part 2 can be prevented.

The seal member 11 can be made of, for example, an elastic material such as rubber.

The holding part 5 has a stepped tube shape and has such a shape that the cross section in the direction perpendicular to the axial direction becomes small stepwise from the cover part 4 side to the cap 6 side.

The holding part 5 is provided inside the hole 2b and is fixed to the bottom of the concave part 2b2. Besides, a part of the holding part 5 on the side where the cross section in the direction perpendicular to the axial direction is small protrudes from the main body part 2. Incidentally, at least a part of the holding part 5 has only to be provided inside the main body part 2. Both ends of the holding part 5 are opened, and the control part 7 is held in the inside.

Although the material of the holding part 5 is not particularly limited, when consideration is given to the fact that the control part 7 is provided inside, the holding part is preferably made of an insulating material. If the holding part 5 has an insulating property, the insulating property against the control part 7 can be ensured.

The material of the holding part 5 is, for example, polybutylene terephthalate (PBT) resin.

The cap part 6 is provided at an end of the holding part 5 on the side protruding from the main body part 2. Thus, one opening of the holding part 5 is closed by the cap part 6.

Besides, a sealing part 13 is provided inside the end of the holding part 5 on the cap 6 side. Thus, when the luminaire 1 is installed outdoors, the intrusion of water or the like into the inside of the luminaire 1 from the gap between the holding part 5 and the cap part 6 can be prevented.

The sealing part 13 can be formed by filling, for example, silicone resin.

Besides, when the holding part 5 is fixed to the bottom of the concave part 2b2, an end face of a stepped portion of the holding part 5 contacts a seal member 12, and the gap between the holding part 5 and the main body part 2 is hermetically sealed. Thus, when the luminaire 1 is installed outdoors, the intrusion of water or the like into the inside of the luminaire 1 from the gap between the holding part 5 and the main body part 2 can be prevented.

The seal member 12 can be made of, for example, an elastic material such as rubber.

The cap part 6 can be made to have a shape attachable to a socket on which a filament bulb is mounted. The cap part 6 can be made to have the same shape as the E26 shape or E17 shape regulated by JIS standards. However, the cap part 6 is not limited to the exemplified shape and can be suitably changed. For example, the cap part 6 may have a pin-shaped terminal used in a fluorescent lamp or may have an L-shaped terminal used in a hook sealing.

The cap part 6 exemplified in FIG. 1 includes a tubular shell part 6a including a screw thread, and an eyelet part 6b provided at an end of the shell part 6a opposite to an end thereof on the main body part 2 side. The shell part 6a and the eyelet part 6b are electrically connected with the control part 7.

The control part 7 is provided in a space formed inside the holding part 5. That is, the control part 7 to control the light-emitting element 3b is provided inside the holding part 5.

The control part 7 may include a lighting circuit to supply power to the light-emitting element 3b. Besides, the control part 7 may include a dimming circuit to dim the light-emitting element 3b.

The space where the control part 7 is provided is hermetically sealed by the cover part 4 and the seal member 11, the holding part 5 and the seal member 12, the cap part 6 and the sealing part 13, and the like.

Besides, when consideration is given to substitution for an existing filament bulb or the like, there is a case where the outer shape and size of the main body part 2 can not be changed.

Thus, there is a case where a space having some degree of volume and hermetically sealed is provided around the control part 7.

When the space as stated above is formed, heat generated in the control part 7 is released by radiation and convection. Thus, a problem may occur that the heat radiation property for the heat generated in the control part 7 is reduced, and a current applied to the light-emitting element 3b can not be increased. Then, the heat transfer part 8 is provided between the control part 7 and the inner wall of the holding part 5, and the heat generated in the control part 7 is released by heat conduction. In this case, the heat transfer part 8 is provided inside an after-mentioned concave part 9b and between the control part 7 and the holding part 5.

Although the material of the heat transfer part 8 is not particularly limited, a material having an insulating property and a high thermal conductivity is preferable. When the heat transfer part 8 has the insulating property, the insulating property against the control part 7 can be ensured.

As the material having the insulating property and the high thermal conductivity, for example, a high heat conduction resin added with ceramic filler having a high thermal conductivity can be exemplified.

In this case, when consideration is given also to fluidity and hardening property when the heat transfer part 8 is formed, for example, silicone resin added with a ceramic filler having a high thermal conductivity can be used.

Here, if the heat transfer part 8 is provided to contact all the area of the control part 7, the volume of the heat transfer part 8 becomes large, and therefore, there is a fear that the weight of the heat transfer part 8, and the weight of the luminaire 1 becomes too heavy. Besides, a cost up is caused.

The temperature of the control part 7 has an in-plane distribution. That is, in the control part 7, the temperature of an area where a current frequently flows becomes high, and the temperature of an area where a current seldom flows becomes low. Besides, there is a tendency that an area of the control part 7 where the temperature becomes high is concentrated on the light source 3 side due to circuit design.

Thus, if the heat transfer part 8 is made to contact only the area where the temperature becomes high in the control part 7, improvement of heat radiation property and suppression of weight increase of the luminaire 1 can be realized.

However, when consideration is given to the forming method of the heat transfer part 8, it is difficult to form the heat transfer part 8 that contacts only the area where the temperature becomes high in the control part 7.

For example, in order to enhance the heat radiation property, an adhesion property between the control part 7 and the heat transfer part 8, and an adhesion property between the inner wall of the holding part 5 and the heat transfer part 8 are required to be enhanced. In this case, after the control part 7 is held inside the holding part 5, a high heat conduction resin or the like is filled between the control part 7 and the inner wall of the holding part 5, and the heat transfer part 8 is formed.

However, if the high heat conduction resin or the like is filled between the control part 7 and the inner wall of the holding part 5, the high heat conduction resin or the like is filled also in the area where the necessity of providing the heat transfer part 8 is low. Thus, there is a fear that the suppression of weight increase of the luminaire 1 can not be realized.

Then, in this embodiment, the area control part 9 to control the area where the heat transfer part 8 is formed is provided.

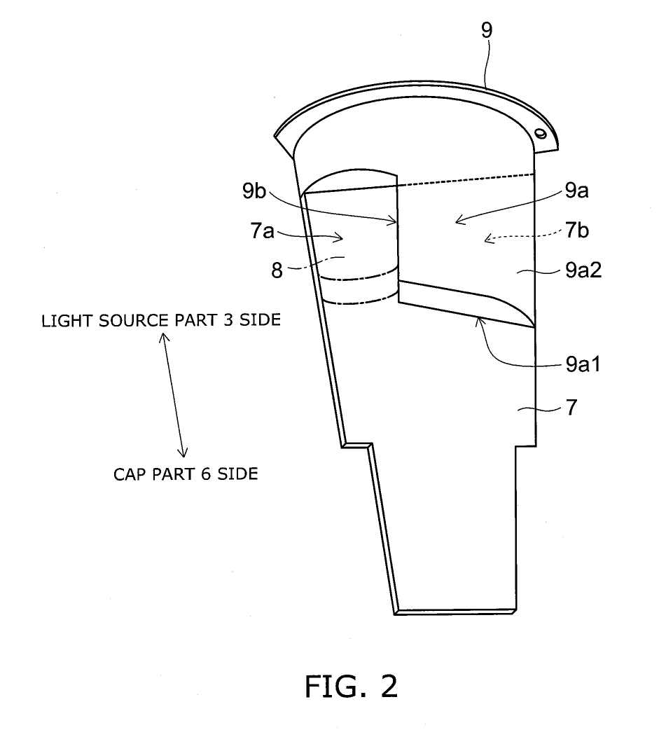

FIG. 2 is a schematic view for exemplifying the area control part 9.

In FIG. 2, it is assumed that the temperature of an area 7a (corresponding to an example of a second area) of the control part 7 on the light source 3 side becomes high, and the temperature of an area 7b (corresponding to an example of a first area) adjacent to this does not become so high.

The area control part 9 is provided with a portion 9a to cover the area 7b, and a concave part 9b adjacent to the portion 9a.

The area 7a is exposed in the concave part 9b. One surface 9a1 of the portion 9a contacts the control part 7, and a surface 9a2 contacts the inner wall of the holding part 5.

That is, the area control part 9 including the concave part 9b is provided between the control part 7 and the holding part 5.

The area 7b where the temperature is not so high is covered with the area control part 9, and the gap between the area 7b and the inner wall of the holding part 5 is embedded with the area control part 9.

On the other hand, the area 7a where the temperature is high is exposed by the concave part 9b, and the heat transfer part 8 covering the area 7a can be formed by filling high heat conduction resin or the like in the inside of the concave part 9b.

That is, the temperature of the area 7a becomes higher than that of the area 7b when the light-emitting element 3b is controlled. The area control part 9 covers the area 7b of the control part 7, and the heat transfer part 8 covers the area 7a of the control part 7. Besides, as stated before, the area 7a can be provided on the light source part 3 side of the control part 7.

The area control part 9 controls the area where the heat transfer part 8 is formed and, further, can conduct the heat generated in the area 7b of the control part 7 and can insulate the area 7b of the control part 7. Besides, the density of the area control part 9 is lower than the density of the heat transfer part 8. For example, the area control part 9 is made to have a hollow structure, so that the density of the area control part 9 can be made low. When doing so, suppression of weight increase of the luminaire 1 can be realized.

Although the material of the area control part 9 is not particularly limited, a material having an insulating property and a low density is preferable. When the area control part 9 is made to have the insulating property, the insulating property against the control part 7 can be ensured.

Further, a material having a high thermal conductivity is more preferable.

The material of the area control part 9 is, for example, polybutylene terephthalate resin.

If the area control part 9 is provided, the heat transfer part 8 is easily formed only in the high temperature area 7a. Thus, the suppression of weight increase of the luminaire 1 can be realized. Besides, the heat radiation property and the insulating property in the area 7b where the temperature is not so high can be improved.

The formation of the heat transfer part 8 and the sealing part 13 can be performed, for example, in a manner as described below.

First, the control part 7 is inserted through the opening of the holding part 5 on the light source part 3 side, and the control part 7 is held inside the holding part 5.

Next, the area control part 9 is inserted through the opening of the holding part 5 on the light source part 3 side, and the area control part 9 is fastened to the holding part 5.

Next, a filling nozzle is inserted through the opening of the holding part 5 on the cap part 6 side, and a high heat conduction resin or the like is filled inside the concave part 9b.

At this time, the heat transfer part 8 can be formed only in a specified area by the area control part 9.

The heat transfer part 8 can be formed in the manner as described above.

Next, the cap part 6 is attached to the end of the holding part 5.

Next, a filling nozzle is inserted through the opening of the holding part 5 on the light source part 3 side, and silicone resin or the like is filled inside the end of the holding part 5 on the cap part 6 side.

The sealing part 13 can be formed in the manner as described above.

Here, as stated before, when consideration is given to the substitution for the existing filament bulb, there is a case where the outer shape and the size of the main body part 2 can not be changed.

Thus, there is a case where a space having some degree of volume and hermetically sealed is formed between the holding part 5 and the main body part 2.

When the space as stated above is formed, the heat conducted to the holding part 5 is released by radiation or convection. Thus, the heat radiation property for the heat generated in the control part 7 is reduced.

In this case, if the thicknesses of the holding part 5 and the main body part 2 are made thick, or a filling material is filled in the space, there is a fear that the weight of the luminaire 1 becomes too heavy.

Then, in this embodiment, a heat transfer part 14 (corresponding to an example of a second heat transfer part) is provided between the holding part 5 and the main body part 2.

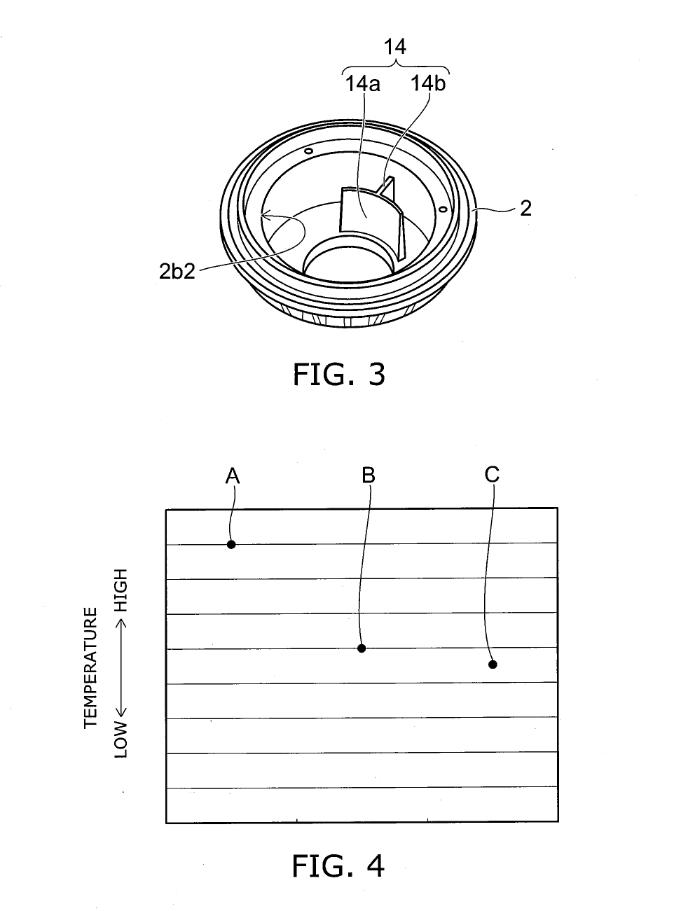

FIG. 3 is a schematic perspective view for exemplifying the heat transfer part 14.

As shown in FIG. 3, the heat transfer part 14 is provided with a heat receiving part 14a and a heat conducting part 14b.

A contact portion of the heat receiving part 14a that contacts the holding part 5 has a plane shape, and at least a part contacts the outer wall of the holding part 5. Besides, the heat receiving part 14a faces the heat transfer part 8 through the holding part 5. That is, the heat receiving part 14a is provided to face the area where the temperature of the control part 7 is high.

Besides, the heat conducting part 14b has a plate shape, and is provided between the heat receiving part 14a and the main body part 2. Thus, the heat generated in the high temperature area 7a is conducted to the main body part 2 through the heat transfer part 8, the holding part 5, the heat receiving part 14a and the heat conducting part 14b, and can be released to the outside from the main body part 2. Besides, the plate-shaped heat conducting part 14b is provided, so that the reduction of weight of the heat transfer part 14 and the suppression of weight increase of the luminaire 1 can be realized.

In this case, the heat receiving part 14a and the heat conducting part 14b may be formed integrally with the main body part 2, or the heat conducting part 14b may be connected to the main body part 2, and the heat receiving part 14a may be connected to the heat conducting part 14b.

Incidentally, if the heat receiving part 14a and the heat conducting part 14b are formed integrally with the main body part 2, heat conduction in the heat transfer part 14 can be efficiently performed.

Although the material of the heat receiving part 14a and the heat conducting part 14b is not particularly limited, a material having a high thermal conductivity is preferable. The heat receiving part 14a and the heat conducting part 14b may be made of, for example, the same material as the main body part 2. For example, the heat transfer part 14 may be made of a metal. If the heat transfer part 14 is made of the metal, the heat conduction in the heat transfer part 14 can be efficiently performed.

Here, if the heat receiving part is formed so as to surround the holding part 5, the weight becomes heavy. Thus, in this embodiment, the heat receiving part 14a is provided in the area facing the heat transfer part 8. Besides, since the contact portion of the heat receiving part 14a that contacts the holding part 5 has the plane shape, the amount of conducted heat can be made large.

Thus, the weight increase of the heat transfer part 14 is suppressed, and the heat radiation property can be improved.

FIG. 4 is a schematic graph for exemplifying effects of the heat transfer part 8 and the heat transfer part 14.

“A” in FIG. 4 denotes a case where the heat transfer part 8 and the heat transfer part 14 are not provided, “B” denotes a case where the heat transfer part 8 is provided, and “C” denotes a case where the heat transfer part 8 and the heat transfer part 14 are provided.

Incidentally, the heat transfer part 8 is provided together with the area control part 9.

As indicated by “B” in FIG. 4, if the heat transfer part 8 is provided, the temperature in the high temperature area 7a of the control part 7 can be reduced by about 30%.

Besides, as indicated by “C” in FIG. 4, if the heat transfer part 8 and the heat transfer part 14 are provided, the temperature in the high temperature area 7a of the control part 7 can be reduced by about 35%.

Besides, as is understood from FIG. 4, if at least one of the heat transfer part 8 and the heat transfer part 14 is provided, the temperature in the high temperature area 7a of the control part 7 can be reduced. However, as indicated by “C” in FIG. 4, if the heat transfer part 8 and the heat transfer part 14 are provided, the temperature in the high temperature area 7a of the control part 7 can be further reduced.

In this case, even if the heat transfer part 8 and the heat transfer part 14 are provided, the amount of weight increase of the luminaire 1 can be made small.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, above-mentioned embodiments can be combined mutually and can be carried out.

What is claimed is:

1. A luminaire comprising:
a main body;
a holding part, at least a part of which is provided inside the main body;
a light source provided in the main body and including a light-emitting element;
a control section for controlling the light-emitting element;
an area control part provided between the control part and the holding part and including a concave section; and
a heat transfer material provided inside the concave section through which heat generated in the control section is transferred to the holding part.

2. The luminaire according to claim 1, further comprising
a heat transfer section that includes a heat receiving part at least a part of which contacts the holding part, and a heat conducting part provided between the heat receiving part and the main body, wherein
the heat receiving part is provided to face the heat transfer material through the holding part.

3. The luminaire according to claim 1, wherein
the area control part covers a first area of the control section, and
the heat transfer material covers a second area of the control section, the second area having a higher temperature than the first area when the control section controls the light-emitting element.

4. The luminaire according to claim 3, wherein the second area of the control section is closer to the light source than the first area.

5. The luminaire according to claim 1, wherein a density of the area control part is lower than a density of the heat transfer material.

6. The luminaire according to claim 1, wherein the area control part is formed from a hollow structure.

7. The luminaire according to claim 1, wherein the heat transfer material has an insulating property.

8. The luminaire according to claim 1, wherein the area control part has an insulating property.

9. The luminaire according to claim 1, wherein the holding part has a tubular shape, one end of which protrudes from the main body, and a sealing part is provided inside the one end of the holding part.

10. A luminaire comprising:
a main body;
a holding part, at least a part of which is provided inside the main body;
a light source provided in the main body and including a light-emitting element;
a control section for controlling the light-emitting element; and
a heat transfer section including a heat receiving part, at least a part of which contacts the holding part and a heat conducting part provided between the heat receiving part and the main body to face a first region of the control section that is at a higher temperature relative to a second region of the control section.

11. The luminaire according to claim 10, wherein a contact portion of the heat receiving part that contacts the holding part has a plane shape, and at least a part of the contact portion contacts an outer wall of the holding part.

12. The luminaire according to claim 10, wherein the heat conducting part has a plate shape.

13. The luminaire according to claim 10, wherein the first region is closer to the light source than the second region.

14. The luminaire according to claim 10, wherein the heat receiving part and the heat conducting part are formed integrally with the main body.

15. The luminaire according to claim 10, wherein the heat transfer section is made of a metal.

16. A method of assembling a luminaire comprising a main body, a holding part provided at a first end of the main body, at least a part of which is provided inside the main body, a light source with a light-emitting element provided at a second end of the main body that is opposite the first end, a cap provided at an end of the holding part that extends away from the main body, a control section for controlling the light-emitting element disposed in the main body between the light source and the cap, and an area control part provided between the control section and the holding part and including a concave section, said method comprising:
inserting the control section and then the area control part through an opening of the holding part that is inside the main body;
inserting a first nozzle through an opening of the holding part that is on a side of the cap;
filling the concave section of the area control part with a high heat-conductive material using the first nozzle;
after said filling, attaching the cap to the end of the holding part extends away from the main body;
inserting a second nozzle through the opening of the holding part that is inside the main body; and
filling the opening of the holding part that is on a side of the cap with silicone resin using the second nozzle to seal the cap.

17. The method of claim 16, wherein the high heat-conductive material is a resin.

18. The method of claim 16, wherein, after said filling the concave section, the high-conductive material is in contact with a first region of the control section that is at a higher temperature relative to a second region of the control section when the control section is controlling light emitting element.

19. The method of claim 16, further comprising:
installing a heat transfer section in contact with the holding part to transfer heat away from the holding part.

20. The method of claim 19, wherein the heat transfer section includes a heat receiving part, at least a part of which contacts the holding part and a heat conducting part provided between the heat receiving part and the main body.
